(19) United States
(12) Patent Application Publication
(10) Pub. No.: US 2024/0105822 A1
(43) Pub. Date: Mar. 28, 2024

(54) STACKED PEROVSKITE FERROELECTRIC FIELD EFFECT TRANSISTOR (FEFET) DEVICES

(71) Applicant: Intel Corporation, Santa Clara, CA (US)

(72) Inventors: Kevin P. O'Brien, Portland, OR (US); Brandon Holybee, Portland, OR (US); Carly Rogan, North Plains, OR (US); Dmitri Evgenievich Nikonov, Beaverton, OR (US); Punyashloka Debashis, Hillsboro, OR (US); Rachel A. Steinhardt, Beaverton, OR (US); Tristan A. Tronic, Aloha, OR (US); Ian Alexander Young, Olympia, WA (US); Marko Radosavljevic, Portland, OR (US); John J. Plombon, Portland, OR (US)

(73) Assignee: Intel Corporation, Santa Clara, CA (US)

(21) Appl. No.: 17/953,648

(22) Filed: Sep. 27, 2022

(51) Int. Cl. H01L 29/775; H01L 29/06; H01L 29/24; H01L 29/423; H01L 29/49; H01L 29/66

(52) U.S. Cl. CPC H01L 29/775; H01L 29/0673; H01L 29/24; H01L 29/42392; H01L 29/4908; H01L 29/66969

(57) ABSTRACT

A transistor device may include a first perovskite gate material, a first perovskite ferroelectric material on the first gate material, a first perovskite semiconductor material on the first ferroelectric material, a second perovskite ferroelectric material on the first semiconductor material, a second perovskite gate material on the second ferroelectric material, a third perovskite ferroelectric material on the second gate material, a second perovskite semiconductor material on the third ferroelectric material, a fourth perovskite ferroelectric material on the second semiconductor material, a third perovskite gate material on the fourth ferroelectric material, a first source/drain metal adjacent a first side of each of the first semiconductor material and the second semiconductor material, a second source/drain metal adjacent a second side opposite the first side of each of the first semiconductor material and the second semiconductor material, and dielectric materials between the source/drain metals and the gate materials.

### BACKGROUND

As computing demand increases, corresponding energy demands increase exponentially. In this scenario, compute limitations may be defined not by the speed of operation, but by the energy needed for operation. To lower energy consumption in compute devices, transistor devices can be designed to use lower operating voltages. However, conventional metal oxide semiconductor field-effect transistor (MOSFET) devices encounter limits on their operating voltage, with their threshold voltage and subthreshold slope dictating the ability to lower currents in the off-state. Numerous efforts to lower the operating voltage of MOSFET devices have, at best, achieved as low as 0.6V, as further lowering of the supply voltage runs in to the device thresholds and results in a drastic decrease in the speed of the MOSFET operation. Ferroelectric field-effect transistor (FeFET) devices are another type of device that has been investigated for use in future compute devices.

### BRIEF DESCRIPTION OF THE DRAWINGS

FIG. 1 illustrates an example stacked transistor device in accordance with embodiments herein.

FIGS. 2A-2B illustrate an example process of manufacturing a stacked perovskite transistor device in accordance with embodiments herein.

FIG. 3 illustrates an example process of etching a sacrificial gate material in a process of manufacturing a stacked perovskite transistor device in accordance with embodiments herein.

FIG. 4 is a top view of a wafer and dies that may be included in a microelectronic assembly, in accordance with any of the embodiments disclosed herein.

FIG. 5 is a cross-sectional side view of an integrated circuit device that may be included in a microelectronic assembly, in accordance with any of the embodiments disclosed herein.

FIG. 6 is a cross-sectional side view of an integrated circuit device assembly that may include a microelectronic assembly, in accordance with any of the embodiments disclosed herein.

FIG. 7 is a block diagram of an example electrical device that may include a microelectronic assembly, in accordance with any of the embodiments disclosed herein.

### DETAILED DESCRIPTION

Embodiments herein describe stacked perovskite transistor devices with lower switching voltages, which may enable increased energy efficiency in circuits (e.g., integrated circuits such as processors) that incorporate them. The stacked perovskite transistor devices may form ribbon field-effect transistor (FET)-like devices but using perovskite materials and ferroelectric-based transistor devices similar to ferroelectric field-effect transistors (FeFETs). The stacked perovskite transistor devices of the present disclosure may enable switching voltages as low as approximately 200 mV and may also enable large on-currents as well, e.g., due to the stacked nature of the device.

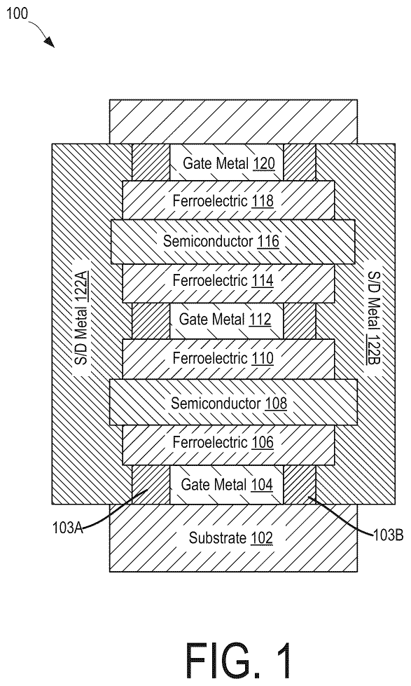

FIG. 1 illustrates an example stacked transistor device 100 in accordance with embodiments herein. In particular, FIG. 1 is a cross-sectional view of the example device 100. The example transistor device 100 includes a substrate 102, on which a stacked transistor is formed. The stacked transistor includes a first gate metal layer 104 on the substrate 102, a first ferroelectric (FE) material 106 on the first gate metal layer 104, a first semiconductor material 108 on the first FE material 106, a second FE material 110 on the first semiconductor material 108, a second gate metal layer 112 on the second FE material 110, a third FE material 114 on the second gate metal layer 112, a second semiconductor material 116 on the third FE material 114, a fourth FE material 118 on the second semiconductor material 116, and a third gate metal layer 120 on the fourth FE material 118. There is also a source/drain (S/D) metal material 122 on either side of the transistor stack as shown, with isolation regions (e.g., 103A, 103B) between the S/D metal materials 122 and the gate metal layers 104, 112, 120. In certain embodiments, such as the one shown, the width of the FE material layers is less than the width of the semiconductor layers to allow for additional contact area between the semiconductor layers and the source/drain metals in the device, which may provide one or more benefits such as lower contact resistance between the semiconductor layers and the source/drain metals.

Each of the gate metal layers, FE material layers, semiconductor layers, and the S/D metals may be perovskite oxide materials in embodiments herein, which may allow for each layer to be deposited within the same, single fabrication chamber (i.e., allow for vacuum to not be broken between the deposition of each layer), creating a continuous perovskite structure (which may also be referred to as a “super lattice” in some instances) across the entirety of the transistor stack. Example perovskite semiconductor materials may include doped BaSnO₃ (e.g., doped with La or other dopants such as neodymium (Nd), Caesium (Cs), Yttrium (Y), or Vanadium (V)). La-doped BaSnO₃ may also be referred to herein and in the Figures as “La—BSO”), doped SrTiO₃ (e.g., doped with La or other dopants such as Nd), IGZO (Indium Gallium Zinc Oxide), LaNiO₃, SrSnO₃, or (Ba—Sr)SnO₃. As used herein, (A-B) (e.g., La—Ba) may refer to elements A and B in proportions AₓB₍₁₋ₓ₎(e.g., LaₓBa₍₁₋ₓ₎SnO₃). The level of La doping (or other dopant) of the perovskite semiconductor material may be in the range of 1-5% in certain embodiments (e.g., LaₓBa₍₁₋ₓ₎SnO₃, where x=1-5%). Example perovskite FE materials may include BaTiO₃ (which may also be referred to herein and in the Figures as “BTO”), Ba(Zr—Ti)O₃, (Ba—Ca)TiO₃, (Ba—Sr)TiO₃, (Ba—Ca)(Ti—Zr)O₃, BiFeO₃, (Bi—La)FeO₃, Bi(Fe—Co)O₃, LiNbO₃, or KNbO₃. The gate metal layers and S/D metal may include SrRuO₃ (which may also be referred to herein and in the Figures as “SRO”), (Sr—Ba)RuO₃, (La—Ba)SnO₃, (La—Sr)MnO₃, (La—Ba)CoO₃, LaNiO₃, LaRuO₃, YBa₂Cu₃O₇, SrVO₃, SrCoO₃, SrMoO₃.

The substrate 102 may include an oxide template material on top of a more typical substrate material. For example, the substrate 102 may include an oxide material layer such as SrTiO₃ (which may also be referred to herein or in the Figures as “STO”) on a silicon-based (e.g., SiO₂) or similar type of substrate material. The isolation regions (e.g., 103) may be a dielectric material, and may include SiN₃ or amorphous BN₃ in certain embodiments. In some instances, the isolation regions may be referred to as “spacers”.

The device 100 may further include conductive vias that are connected to the gate metal layers into and/or out of the page, e.g., similar to the source/drain metals shown. In addition, while the example device 100 includes what are effectively two stacked transistors, some embodiments may include further layers in the stack, e.g., to create what are effectively 3-10 (or more) stacked transistors. For example, in addition to the layers shown, the device may include a first additional FE material on the third gate metal layer 120, an additional semiconductor material on the first additional FE material, a second additional FE material on the additional semiconductor material, and a fourth gate metal layer on the second additional FE material.

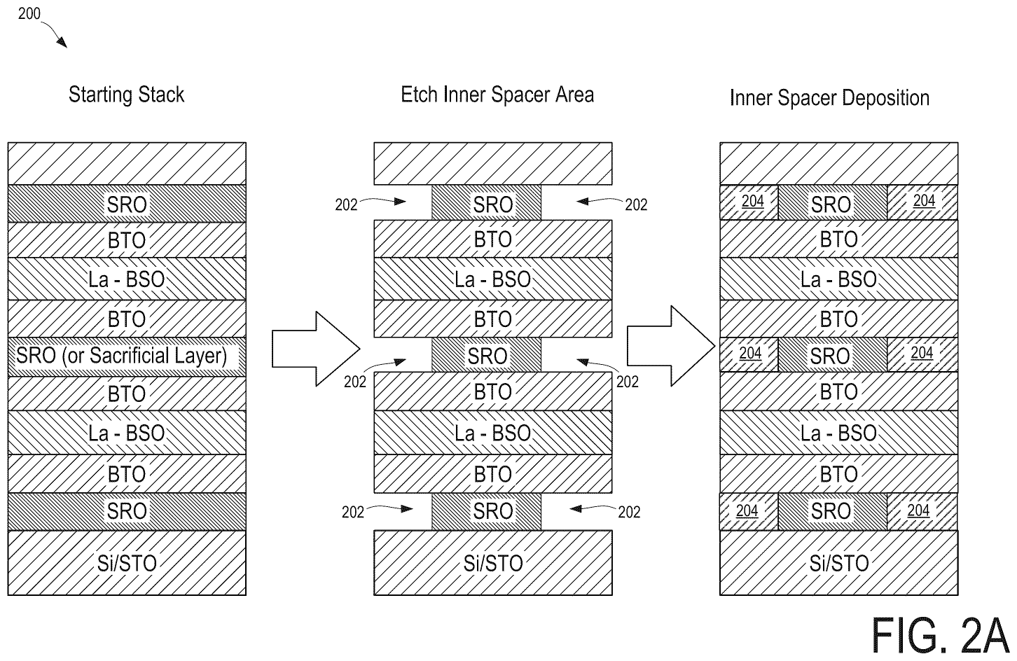

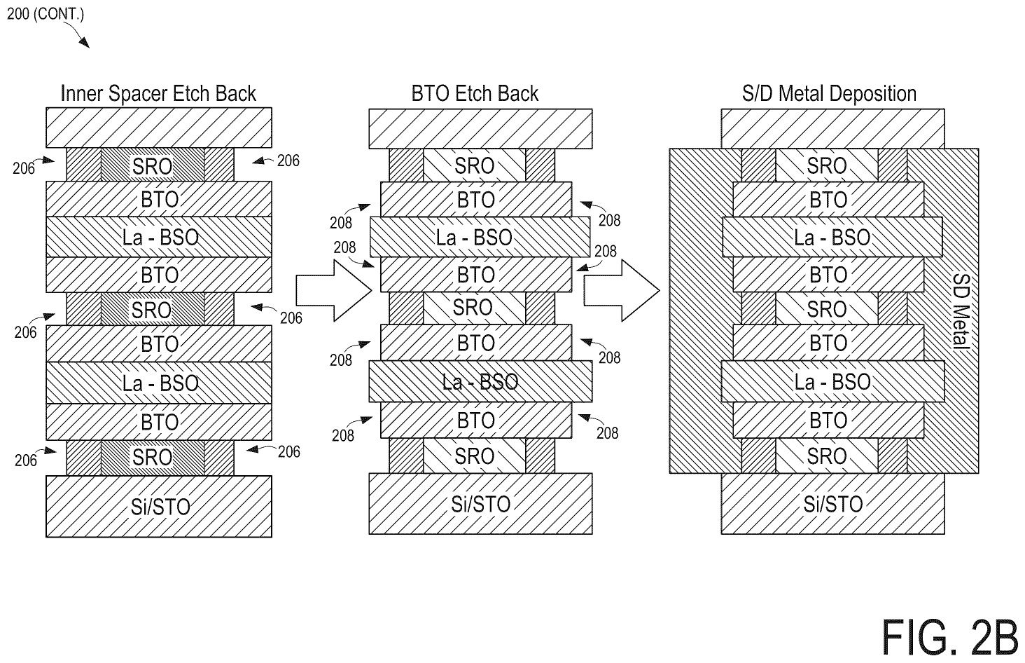

FIGS. 2A-2B illustrate an example process 200 of manufacturing a stacked perovskite transistor device in accordance with embodiments herein. The example process shown may include additional, fewer, or different operations than those shown or described below. In some embodiments, one or more of the operations shown in FIGS. 2A-2B include multiple operations, sub-operations, etc.

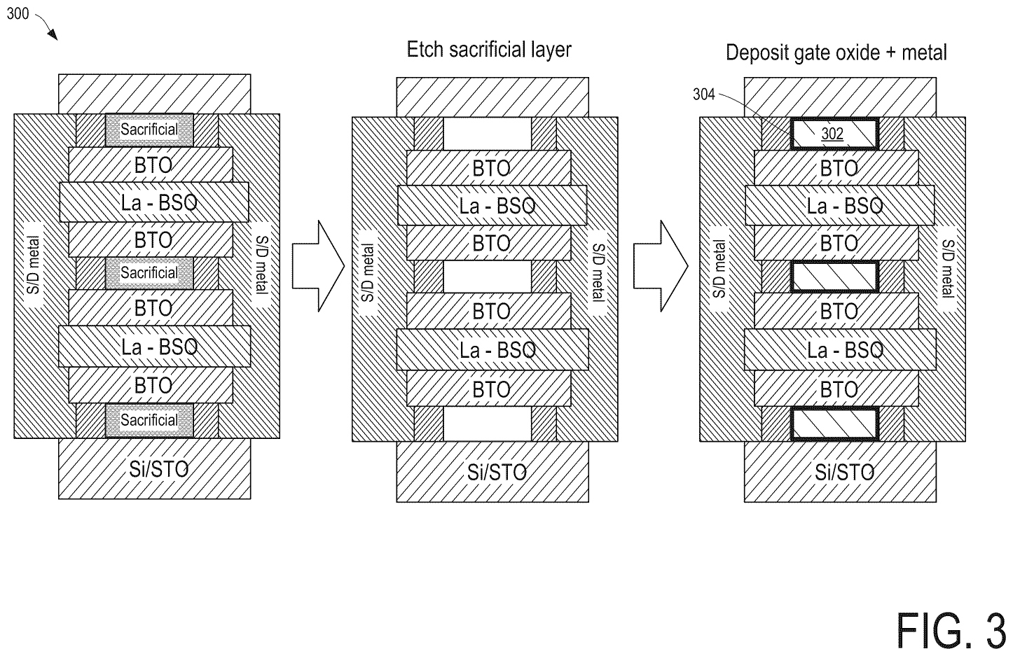

As shown by the left image in FIG. 2A, the process 200 begins with a stack of material layers, similar to the stack described above. The stack includes a Si-based substrate with STO with a first SRO layer (or in other embodiments, e.g., as shown in FIG. 3 a sacrificial material layer) on the substrate, a first BTO layer on the first SRO layer, a first La—BSO layer on the first SRO layer, a second BTO layer on the first La—BSO layer, a second SRO layer (or in other embodiments, e.g., as shown in FIG. 3 a sacrificial material layer) on the second BTO layer, a third BTO layer on the second SRO layer, a second La—BSO layer on the third BTO layer, a fourth BTO layer on the second La—BSO layer, and a third SRO layer (or in other embodiments, e.g., as shown in FIG. 3 a sacrificial material layer) on the fourth BTO layer. Although particular example materials are used in the stack shown in FIGS. 2A-2B, other materials may be used instead, e.g., those described above with respect to FIG. 1.

Next, inner spacer areas 202 are etched (e.g., via a dry etch or other suitable technique) away as shown in the middle image of FIG. 2A. Then, as shown in the right image of FIG. 2A, the inner isolation regions/spacers 204 are deposited (e.g., via atomic layer deposition (ALD) or another suitable technique) in the etched back spacer areas 202. The isolation regions/spacers 204 are then etched back (e.g., via a vapor etch, atomic layer etch (ALE), wet etch, or other suitable technique) as shown in the areas 206 of the left image of FIG. 2B, and the BTO layers are also etched back (e.g., via a vapor etch, ALD or another suitable technique) as shown in the areas 208 of the middle image of FIG. 2B. Etching back the BTO as shown can expose more of the La—BSO layer to the source/drain metal, which is then deposited on each side of the stack as shown in the right image of FIG. 2B.

FIG. 3 illustrates an example process 300 of etching a sacrificial gate material in a process of manufacturing a stacked perovskite transistor device in accordance with embodiments herein. In particular, the process 300 shows additional operations that can be performed in the process 200 described above when a sacrificial material is used in place of the SRO material. For instance, the left image of FIG. 3 illustrates a stack that may have been manufactured according to the process 200 of FIGS. 2A-2B, except with a sacrificial material in place of the SRO layers in the stack. The sacrificial material may then be selectively etched away as shown in the middle image of FIG. 3, and a gate oxide 304 and gate metal 302 can then be deposited in its place as shown in the right image of FIG. 3. In some embodiments, however, a gate metal 302 may be deposited without the gate oxide layer 304. The gate oxide layer 304 may stop leakage between the BTO layer and the gate metal, in certain instances.

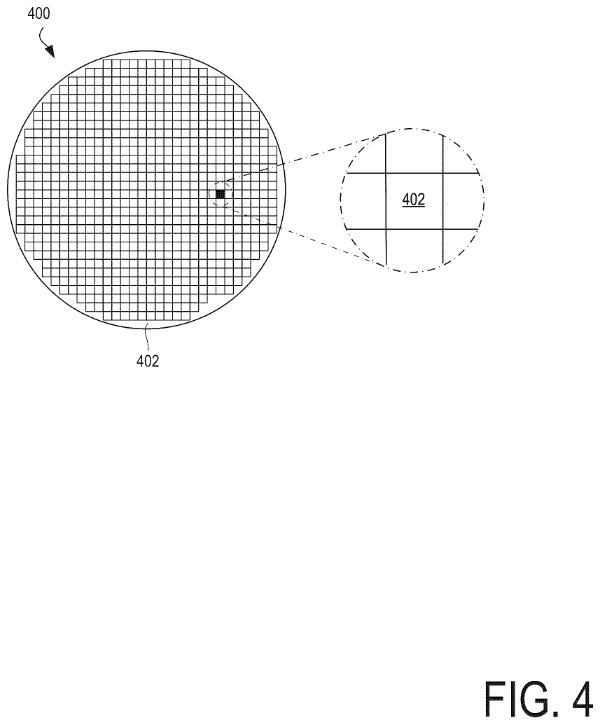

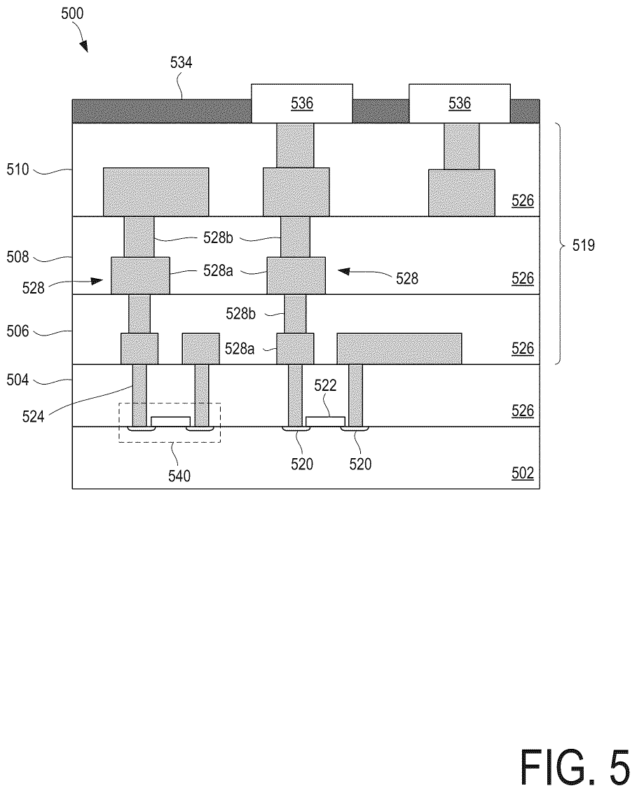

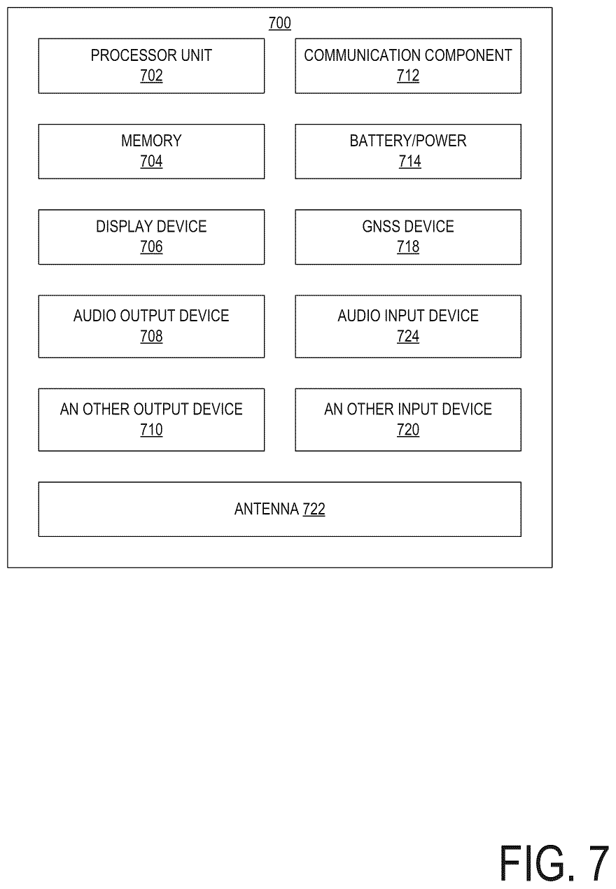

FIG. 4 is a top view of a wafer 400 and dies 402 that may incorporate any of the embodiments disclosed herein. The wafer 400 may be composed of semiconductor material and may include one or more dies 402 having integrated circuit structures formed on a surface of the wafer 400. The individual dies 402 may be a repeating unit of an integrated circuit product that includes any suitable integrated circuit. After the fabrication of the semiconductor product is complete, the wafer 400 may undergo a singulation process in which the dies 402 are separated from one another to provide discrete “chips” of the integrated circuit product. The die 402 may include one or more transistors (e.g., some of the transistors 540 of FIG. 5, discussed below), supporting circuitry to route electrical signals to the transistors, passive components (e.g., signal traces, resistors, capacitors, or inductors), and/or any other integrated circuit components. In some embodiments, the wafer 400 or the die 402 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 402. For example, a memory array formed by multiple memory devices may be formed on a same die 402 as a processor unit (e.g., the processor unit 702 of FIG. 7) or other logic that is configured to store information in the memory devices or execute instructions stored in the memory array.

FIG. 5 is a cross-sectional side view of an integrated circuit device 500 that may be included in any of the embodiments disclosed herein. One or more of the integrated circuit devices 500 may be included in one or more dies 402 (FIG. 4). The integrated circuit device 500 may be formed on a die substrate 502 (e.g., the wafer 400 of FIG. 4) and may be included in a die (e.g., the die 402 of FIG. 4). The die substrate 502 may be a semiconductor substrate composed of semiconductor material systems including, for example, n-type or p-type materials systems (or a combination of both). The die substrate 502 may include, for example, a crystalline substrate formed using a bulk silicon or a silicon-on-insulator (SOI) substructure. In some embodiments, the die substrate 502 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 502. Although a few examples of materials from which the die substrate 502 may be formed are described here, any material that may serve as a foundation for an integrated circuit device 500 may be used. The die substrate 502 may be part of a singulated die (e.g., the dies 402 of FIG. 4) or a wafer (e.g., the wafer 400 of FIG. 4).

The integrated circuit device 500 may include one or more device layers 504 disposed on the die substrate 502. The device layer 504 may include features of one or more transistors 540 (e.g., metal oxide semiconductor field-effect transistors (MOSFETs)) formed on the die substrate 502. The transistors 540 may include, for example, one or more source and/or drain (S/D) regions 520, a gate 522 to control current flow between the S/D regions 520, and one or more S/D contacts 524 to route electrical signals to/from the S/D regions 520. The transistors 540 may include additional features not depicted for the sake of clarity, such as device isolation regions, gate contacts, and the like. The transistors 540 are not limited to the type and configuration depicted in FIG. 5 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 5, a transistor 540 may include a gate 522 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 540 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 540 along the source-channel-drain direction, the gate electrode may consist of a U-shaped structure that includes a bottom portion substantially parallel to the surface of the die substrate 502 and two sidewall portions that are substantially perpendicular to the top surface of the die substrate 502. In other embodiments, at least one of the metal layers that form the gate electrode may simply be a planar layer that is substantially parallel to the top surface of the die substrate 502 and does not include sidewall portions substantially perpendicular to the top surface of the die substrate 502. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 520 may be formed within the die substrate 502 adjacent to the gate 522 of individual transistors 540. The S/D regions 520 may be formed using an implantation/diffusion process or an etching/deposition process, for example. In the former process, dopants such as boron, aluminum, antimony, phosphorous, or arsenic may be ion-implanted into the die substrate 502 to form the S/D regions 520. An annealing process that activates the dopants and causes them to diffuse farther into the die substrate 502 may follow the ion-implantation process. In the latter process, the die substrate 502 may first be etched to form recesses at the locations of the S/D regions 520. An epitaxial deposition process may then be carried out to fill the recesses with material that is used to fabricate the S/D regions 520. In some implementations, the S/D regions 520 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 520 may be formed using one or more alternate semiconductor materials such as germanium or a group III-V material or alloy. In further embodiments, one or more layers of metal and/or metal alloys may be used to form the S/D regions 520.

Electrical signals, such as power and/or input/output (I/O) signals, may be routed to and/or from the devices (e.g., transistors 540) of the device layer 504 through one or more interconnect layers disposed on the device layer 504 (illustrated in FIG. 5 as interconnect layers 506-510). For example, electrically conductive features of the device layer 504 (e.g., the gate 522 and the S/D contacts 524) may be electrically coupled with the interconnect structures 528 of the interconnect layers 506-510. The one or more interconnect layers 506-510 may form a metallization stack (also referred to as an “ILD stack”) 519 of the integrated circuit device 500.

The interconnect structures 528 may be arranged within the interconnect layers 506-510 to route electrical signals according to a wide variety of designs; in particular, the arrangement is not limited to the particular configuration of interconnect structures 528 depicted in FIG. 5. Although a particular number of interconnect layers 506-510 is depicted in FIG. 5, embodiments of the present disclosure include integrated circuit devices having more or fewer interconnect layers than depicted.

In some embodiments, the interconnect structures 528 may include lines 528a and/or vias 528b filled with an electrically conductive material such as a metal. The lines 528a may be arranged to route electrical signals in a direction of a plane that is substantially parallel with a surface of the die substrate 502 upon which the device layer 504 is formed. For example, the lines 528a may route electrical signals in a direction in and out of the page and/or in a direction across the page from the perspective of FIG. 5. The vias 528b may be arranged to route electrical signals in a direction of a plane that is substantially perpendicular to the surface of the die substrate 502 upon which the device layer 504 is formed. In some embodiments, the vias 528b may electrically couple lines 528a of different interconnect layers 506-510 together.

The interconnect layers 506-510 may include a dielectric material 526 disposed between the interconnect structures 528, as shown in FIG. 5. In some embodiments, dielectric material 526 disposed between the interconnect structures 528 in different ones of the interconnect layers 506-510 may have different compositions; in other embodiments, the composition of the dielectric material 526 between different interconnect layers 506-510 may be the same. The device layer 504 may include a dielectric material 526 disposed between the transistors 540 and a bottom layer of the metallization stack as well. The dielectric material 526 included in the device layer 504 may have a different composition than the dielectric material 526 included in the interconnect layers 506-510; in other embodiments, the composition of the dielectric material 526 in the device layer 504 may be the same as a dielectric material 526 included in any one of the interconnect layers 506-510.

A first interconnect layer 506 (referred to as Metal 1 or “M1”) may be formed directly on the device layer 504. In some embodiments, the first interconnect layer 506 may include lines 528a and/or vias 528b, as shown. The lines 528a of the first interconnect layer 506 may be coupled with contacts (e.g., the S/D contacts 524) of the device layer 504. The vias 528b of the first interconnect layer 506 may be coupled with the lines 528a of a second interconnect layer 508.

The second interconnect layer 508 (referred to as Metal 2 or “M2”) may be formed directly on the first interconnect layer 506. In some embodiments, the second interconnect layer 508 may include via 528b to couple the lines 528 of the second interconnect layer 508 with the lines 528a of a third interconnect layer 510. Although the lines 528a and the vias 528b are structurally delineated with a line within individual interconnect layers for the sake of clarity, the lines 528a and the vias 528b may be structurally and/or materially contiguous (e.g., simultaneously filled during a dual-damascene process) in some embodiments.

The third interconnect layer 510 (referred to as Metal 3 or “M3”) (and additional interconnect layers, as desired) may be formed in succession on the second interconnect layer 508 according to similar techniques and configurations described in connection with the second interconnect layer 508 or the first interconnect layer 506. In some embodiments, the interconnect layers that are “higher up” in the metallization stack 519 in the integrated circuit device 500 (i.e., farther away from the device layer 504) may be thicker that the interconnect layers that are lower in the metallization stack 519, with lines 528a and vias 528b in the higher interconnect layers being thicker than those in the lower interconnect layers.

The integrated circuit device 500 may include a solder resist material 534 (e.g., polyimide or similar material) and one or more conductive contacts 536 formed on the interconnect layers 506-510. In FIG. 5, the conductive contacts 536 are illustrated as taking the form of bond pads. The conductive contacts 536 may be electrically coupled with the interconnect structures 528 and configured to route the electrical signals of the transistor(s) 540 to external devices. For example, solder bonds may be formed on the one or more conductive contacts 536 to mechanically and/or electrically couple an integrated circuit die including the integrated circuit device 500 with another component (e.g., a printed circuit board). The integrated circuit device 500 may include additional or alternate structures to route the electrical signals from the interconnect layers 506-510; for example, the conductive contacts 536 may include other analogous features (e.g., posts) that route the electrical signals to external components.

In some embodiments in which the integrated circuit device 500 is a double-sided die, the integrated circuit device 500 may include another metallization stack (not shown) on the opposite side of the device layer(s) 504. This metallization stack may include multiple interconnect layers as discussed above with reference to the interconnect layers 506-510, to provide conductive pathways (e.g., including conductive lines and vias) between the device layer(s) 504 and additional conductive contacts (not shown) on the opposite side of the integrated circuit device 500 from the conductive contacts 536.

In other embodiments in which the integrated circuit device 500 is a double-sided die, the integrated circuit device 500 may include one or more through silicon vias (TSVs) through the die substrate 502; these TSVs may make contact with the device layer(s) 504, and may provide conductive pathways between the device layer(s) 504 and additional conductive contacts (not shown) on the opposite side of the integrated circuit device 500 from the conductive contacts 536. In some embodiments, TSVs extending through the substrate can be used for routing power and ground signals from conductive contacts on the opposite side of the integrated circuit device 500 from the conductive contacts 536 to the transistors 540 and any other components integrated into the die 500, and the metallization stack 519 can be used to route I/O signals from the conductive contacts 536 to transistors 540 and any other components integrated into the die 500.

Multiple integrated circuit devices 500 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

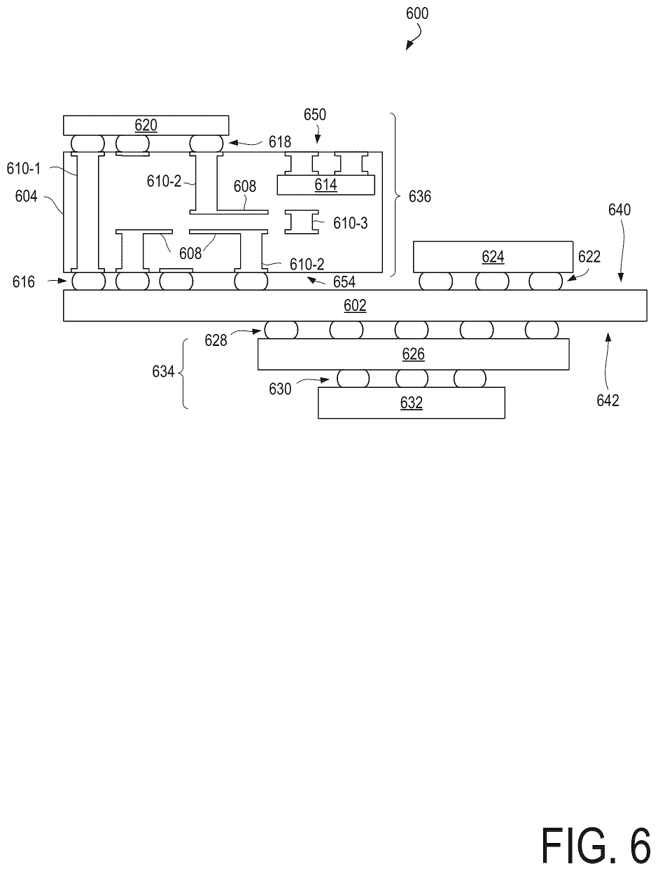

FIG. 6 is a cross-sectional side view of an integrated circuit device assembly 600 that may include any of the embodiments disclosed herein. The integrated circuit device assembly 600 includes a number of components disposed on a circuit board 602 (which may be a motherboard, system board, mainboard, etc.). The integrated circuit device assembly 600 includes components disposed on a first face 640 of the circuit board 602 and an opposing second face 642 of the circuit board 602; generally, components may be disposed on one or both faces 640 and 642.

In some embodiments, the circuit board 602 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 602. In other embodiments, the circuit board 602 may be a non-PCB substrate. The integrated circuit device assembly 600 illustrated in FIG. 6 includes a package-on-interposer structure 636 coupled to the first face 640 of the circuit board 602 by coupling components 616. The coupling components 616 may electrically and mechanically couple the package-on-interposer structure 636 to the circuit board 602, and may include solder balls (as shown in FIG. 6), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 636 may include an integrated circuit component 620 coupled to an interposer 604 by coupling components 618. The coupling components 618 may take any suitable form for the application, such as the forms discussed above with reference to the coupling components 616. Although a single integrated circuit component 620 is shown in FIG. 6, multiple integrated circuit components may be coupled to the interposer 604; indeed, additional interposers may be coupled to the interposer 604. The interposer 604 may provide an intervening substrate used to bridge the circuit board 602 and the integrated circuit component 620.

The integrated circuit component 620 may be a packaged or unpacked integrated circuit product that includes one or more integrated circuit dies (e.g., the die 402 of FIG. 4, the integrated circuit device 500 of FIG. 5) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 620, a single monolithic integrated circuit die comprises solder bumps attached to contacts on the die. The solder bumps allow the die to be directly attached to the interposer 604. The integrated circuit component 620 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 620 can comprise one or more additional active or passive devices such as capacitors, decoupling capacitors, resistors, inductors, fuses, diodes, transformers, sensors, electrostatic discharge (ESI)) devices, and memory devices.

In embodiments where the integrated circuit component 620 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 620 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 604 may spread connections to a wider pitch or reroute a connection to a different connection. For example, the interposer 604 may couple the integrated circuit component 620 to a set of ball grid array (BGA) conductive contacts of the coupling components 616 for coupling to the circuit board 602. In the embodiment illustrated in FIG. 6, the integrated circuit component 620 and the circuit board 602 are attached to opposing sides of the interposer 604; in other embodiments, the integrated circuit component 620 and the circuit board 602 may be attached to a same side of the interposer 604. In some embodiments, three or more components may be interconnected by way of the interposer 604.

In some embodiments, the interposer 604 may be formed as a PCB, including multiple metal layers separated from one another by layers of dielectric material and interconnected by electrically conductive vias. In some embodiments, the interposer 604 may be formed of an epoxy resin, a fiberglass-reinforced epoxy resin, an epoxy resin with inorganic fillers, a ceramic material, or a polymer material such as polyimide. In some embodiments, the interposer 604 may be formed of alternate rigid or flexible materials that may include the same materials described above for use in a semiconductor substrate, such as silicon, germanium, and other group III-V and group IV materials. The interposer 604 may include metal interconnects 608 and vias 610, including but not limited to through hole vias 610-1 (that extend from a first face 650 of the interposer 604 to a second face 654 of the interposer 604), blind vias 610-2 (that extend from the first or second faces 650 or 654 of the interposer 604 to an internal metal layer), and buried vias 610-3 (that connect internal metal layers).

In some embodiments, the interposer 604 can comprise a silicon interposer. Through silicon vias (TSV) extending through the silicon interposer can connect connections on a first face of a silicon interposer to an opposing second face of the silicon interposer. In some embodiments, an interposer 604 comprising a silicon interposer can further comprise one or more routing layers to route connections on a first face of the interposer 604 to an opposing second face of the interposer 604.

The interposer 604 may further include embedded devices 614, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 604. The package-on-interposer structure 636 may take the form of any of the package-on-interposer structures known in the art. In embodiments where the interposer is a non-printed circuit board

The integrated circuit device assembly 600 may include an integrated circuit component 624 coupled to the first face 640 of the circuit board 602 by coupling components 622. The coupling components 622 may take the form of any of the embodiments discussed above with reference to the coupling components 616, and the integrated circuit component 624 may take the form of any of the embodiments discussed above with reference to the integrated circuit component 620.

The integrated circuit device assembly 600 illustrated in FIG. 6 includes a package-on-package structure 634 coupled to the second face 642 of the circuit board 602 by coupling components 628. The package-on-package structure 634 may include an integrated circuit component 626 and an integrated circuit component 632 coupled together by coupling components 630 such that the integrated circuit component 626 is disposed between the circuit board 602 and the integrated circuit component 632. The coupling components 628 and 630 may take the form of any of the embodiments of the coupling components 616 discussed above, and the integrated circuit components 626 and 632 may take the form of any of the embodiments of the integrated circuit component 620 discussed above. The package-on-package structure 634 may be configured in accordance with any of the package-on-package structures known in the art.

FIG. 7 is a block diagram of an example electrical device 700 that may include one or more of the embodiments disclosed herein. For example, any suitable ones of the components of the electrical device 700 may include one or more of the integrated circuit device assemblies 600, integrated circuit components 620, integrated circuit devices 500, or integrated circuit dies 402 disclosed herein. A number of components are illustrated in FIG. 7 as included in the electrical device 700, but any one or more of these components may be omitted or duplicated, as suitable for the application. In some embodiments, some or all of the components included in the electrical device 700 may be attached to one or more motherboards mainboards, or system boards. In some embodiments, one or more of these components are fabricated onto a single system-on-a-chip (SoC) die.

Additionally, in various embodiments, the electrical device 700 may not include one or more of the components illustrated in FIG. 7, but the electrical device 700 may include interface circuitry for coupling to the one or more components. For example, the electrical device 700 may not include a display device 706, but may include display device interface circuitry (e.g., a connector and driver circuitry) to which a display device 706 may be coupled. In another set of examples, the electrical device 700 may not include an audio input device 724 or an audio output device 708, but may include audio input or output device interface circuitry (e.g., connectors and supporting circuitry) to which an audio input device 724 or audio output device 708 may be coupled.

The electrical device 700 may include one or more processor units 702 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 702 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 700 may include a memory 704, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 704 may include memory that is located on the same integrated circuit die as the processor unit 702. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 700 can comprise one or more processor units 702 that are heterogeneous or asymmetric to another processor unit 702 in the electrical device 700. There can be a variety of differences between the processing units 702 in a system in terms of a spectrum of metrics of merit including architectural, microarchitectural, thermal, power consumption characteristics, and the like. These differences can effectively manifest themselves as asymmetry and heterogeneity among the processor units 702 in the electrical device 700.

In some embodiments, the electrical device 700 may include a communication component 712 (e.g., one or more communication components). For example, the communication component 712 can manage wireless communications for the transfer of data to and from the electrical device 700. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 712 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 712 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 712 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 712 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 712 may operate in accordance with other wireless protocols in other embodiments. The electrical device 700 may include an antenna 722 to facilitate wireless communications and/or to receive other wireless communications (such as AM or FM radio transmissions).

In some embodiments, the communication component 712 may manage wired communications, such as electrical, optical, or any other suitable communication protocols (e.g., IEEE 802.3 Ethernet standards). As noted above, the communication component 712 may include multiple communication components. For instance, a first communication component 712 may be dedicated to shorter-range wireless communications such as Wi-Fi or Bluetooth, and a second communication component 712 may be dedicated to longer-range wireless communications such as global positioning system (GPS), EDGE, GPRS, CDMA, WiMAX, LTE, EV-DO, or others. In some embodiments, a first communication component 712 may be dedicated to wireless communications, and a second communication component 712 may be dedicated to wired communications.

The electrical device 700 may include battery/power circuitry 714. The battery/power circuitry 714 may include one or more energy storage devices (e.g., batteries or capacitors) and/or circuitry for coupling components of the electrical device 700 to an energy source separate from the electrical device 700 (e.g., AC line power).

The electrical device 700 may include a display device 706 (or corresponding interface circuitry, as discussed above). The display device 706 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 700 may include an audio output device 708 (or corresponding interface circuitry, as discussed above). The audio output device 708 may include any embedded or wired or wirelessly connected external device that generates an audible indicator, such speakers, headsets, or earbuds.

The electrical device 700 may include an audio input device 724 (or corresponding interface circuitry, as discussed above). The audio input device 724 may include any embedded or wired or wirelessly connected device that generates a signal representative of a sound, such as microphones, microphone arrays, or digital instruments (e.g., instruments having a musical instrument digital interface (MIDI) output). The electrical device 700 may include a Global Navigation Satellite System (GNSS) device 718 (or corresponding interface circuitry, as discussed above), such as a Global Positioning System (GPS) device. The GNSS device 718 may be in communication with a satellite-based system and may determine a geolocation of the electrical device 700 based on information received from one or more GNSS satellites, as known in the art.

The electrical device 700 may include an other output device 710 (or corresponding interface circuitry, as discussed above). Examples of the other output device 710 may include an audio codec, a video codec, a printer, a wired or wireless transmitter for providing information to other devices, or an additional storage device.

The electrical device 700 may include another input device 720 (or corresponding interface circuitry, as discussed above). Examples of the other input device 720 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 700 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 700 may be any other electronic device that processes data. In some embodiments, the electrical device 700 may comprise multiple discrete physical components. Given the range of devices that the electrical device 700 can be manifested as in various embodiments, in some embodiments, the electrical device 700 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is a stacked transistor device comprising: a first perovskite gate material; a first perovskite ferroelectric material on the first perovskite gate material; a first perovskite semiconductor material on the first perovskite ferroelectric material; a second perovskite ferroelectric material on the first perovskite semiconductor material; a second perovskite gate material on the second perovskite ferroelectric material; a third perovskite ferroelectric material on the second perovskite gate material; a second perovskite semiconductor material on the third perovskite ferroelectric material; a fourth perovskite ferroelectric material on the second perovskite semiconductor material; a third perovskite gate material on the fourth perovskite ferroelectric material; a first source/drain metal adjacent a first side of each of the first perovskite semiconductor material and the second perovskite semiconductor material; a second source/drain metal adjacent a second side opposite the first side of each of the first perovskite semiconductor material and the second perovskite semiconductor material; and dielectric materials between the source/drain metals and the perovskite gate materials.

Example 2 includes the subject matter of Example 1, wherein the first perovskite gate material, the first perovskite ferroelectric material, the first perovskite semiconductor material, the second perovskite ferroelectric material, the second perovskite gate material, the third perovskite ferroelectric material, the second perovskite semiconductor material, the fourth perovskite ferroelectric material, and the third perovskite gate material form a continuous perovskite structure.

Example 3 includes the subject matter of Example 1 or 2, wherein a width of the first perovskite semiconductor material and a width of the second perovskite semiconductor material are greater than a width of each of the first perovskite ferroelectric material, the second perovskite ferroelectric material, the third perovskite ferroelectric material, and the fourth perovskite ferroelectric material.

Example 4 includes the subject matter of any one of Example 1-3, wherein first perovskite gate material, the second perovskite gate material, and the third perovskite gate material comprise Strontium, Ruthenium, and Oxygen.

Example 5 includes the subject matter of any one of Examples 1-4, wherein the first perovskite ferroelectric material, the second perovskite ferroelectric material, the third perovskite ferroelectric material, and the fourth perovskite ferroelectric material comprise Barium, Titanium, and Oxygen.

Example 6 includes the subject matter of any one of Examples 1-5, wherein the first perovskite semiconductor material and the second perovskite semiconductor material comprise Lanthanum, Barium, Tin, and Oxygen.

Example 7 includes the subject matter of Example 6, wherein the Lanthanum is between 1% and 5% of the total of Lanthanum and Barium in the first perovskite semiconductor material and the second perovskite semiconductor material.

Example 8 includes the subject matter of any one of Examples 1-7, wherein the dielectric materials between the source/drain metals and the perovskite gate materials comprise Silicon and Nitrogen.

Example 9 includes the subject matter of any one of Examples 1-7, wherein the dielectric materials between the source/drain metals and the perovskite gate materials comprise Boron and Nitrogen.

Example 10 includes the subject matter of any one of Examples 1-9, further comprising a substrate, the first perovskite gate material on the substrate.

Example 11 includes the subject matter of Example 10, wherein the substrate comprises Strontium, Titanium, and Oxygen.

Example 12 is an integrated circuit device comprising: a plurality of stacked transistors according to any one of Examples 1-11; and one or more interconnect layers, the interconnect layers electrically connecting the transistors.

Example 13 is a method of forming a stacked transistor device, comprising: forming a first perovskite gate material on a substrate; forming a first perovskite ferroelectric material on the first perovskite gate material; forming a first perovskite semiconductor material on the first perovskite ferroelectric material; forming a second perovskite ferroelectric material on the first perovskite semiconductor material; forming a second perovskite gate material on the second perovskite ferroelectric material; forming a third perovskite ferroelectric material on the second perovskite gate material; forming a second perovskite semiconductor material on the third perovskite ferroelectric material; forming a fourth perovskite ferroelectric material on the second perovskite semiconductor material; forming a third perovskite gate material on the fourth perovskite ferroelectric material; forming a first source/drain metal adjacent a first side of each of the first perovskite semiconductor material and the second perovskite semiconductor material; and forming a second source/drain metal adjacent a second side opposite the first side of each of the first perovskite semiconductor material and the second perovskite semiconductor material.

Example 14 includes the subject matter of Example 13, wherein the first perovskite gate material, the first perovskite ferroelectric material, the first perovskite semiconductor material, the second perovskite ferroelectric material, the second perovskite gate material, the third perovskite ferroelectric material, the second perovskite semiconductor material, the fourth perovskite ferroelectric material, and the third perovskite gate material are formed without breaking a vacuum.

Example 15 includes the subject matter of Example 13 or 14, further comprising, before forming the first source/drain metal and the second source/drain metal: laterally etching each side of the first perovskite gate material, the second perovskite gate material, and the third perovskite gate material; and forming dielectric materials adjacent on each side of the first perovskite gate material, the second perovskite gate material, and the third perovskite gate material.

Example 16 includes the subject matter of Example 24, further comprising laterally etching each side of the dielectric materials.

Example 17 includes the subject matter of any one of Examples 13-16, further comprising, before forming the first source/drain metal and the second source/drain metal, laterally etching each side of the first perovskite ferroelectric material, the second perovskite ferroelectric material, the third perovskite ferroelectric material, and the fourth perovskite ferroelectric material.

Example 18 includes the subject matter of any one of Examples 13-17, wherein first perovskite gate material, the second perovskite gate material, and the third perovskite gate material comprise Strontium, Ruthenium, and Oxygen.

Example 19 includes the subject matter of any one of Examples 13-18, wherein the first perovskite ferroelectric material, the second perovskite ferroelectric material, the third perovskite ferroelectric material, and the fourth perovskite ferroelectric material comprise Barium, Titanium, and Oxygen.

Example 20 includes the subject matter of any one of Examples 13-19, wherein the first perovskite semiconductor material and the second perovskite semiconductor material comprise Lanthanum, Barium, Tin, and Oxygen.

Example 21 includes the subject matter of Example 20, wherein the Lanthanum is between 1% and 5% of the total of Lanthanum and Barium in the first perovskite semiconductor material and the second perovskite semiconductor material.

Example 22 includes the subject matter of any one of Examples 13-21, wherein the dielectric materials between the source/drain metals and the perovskite gate materials comprise Silicon and Nitrogen.

Example 23 includes the subject matter of any one of Examples 13-21, wherein the dielectric materials between the source/drain metals and the perovskite gate materials comprise Boron and Nitrogen.

Example 24 includes the subject matter of any one of Examples 13-23, wherein the substrate comprises Strontium, Titanium, and Oxygen.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

In various embodiments, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

In various embodiments, the term “adjacent” refers to layers or components that are in physical contact with each other. That is, there is no layer or component between the stated adjacent layers or components. For example, a layer X that is adjacent to a layer Y refers to a layer that is in physical contact with layer Y.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. A stacked transistor device comprising:
a first perovskite gate material;
a first perovskite ferroelectric material on the first perovskite gate material;
a first perovskite semiconductor material on the first perovskite ferroelectric material;
a second perovskite ferroelectric material on the first perovskite semiconductor material;
a second perovskite gate material on the second perovskite ferroelectric material;
a third perovskite ferroelectric material on the second perovskite gate material;
a second perovskite semiconductor material on the third perovskite ferroelectric material;
a fourth perovskite ferroelectric material on the second perovskite semiconductor material;
a third perovskite gate material on the fourth perovskite ferroelectric material;
a first source/drain metal adjacent a first side of each of the first perovskite semiconductor material and the second perovskite semiconductor material;
a second source/drain metal adjacent a second side opposite the first side of each of the first perovskite semiconductor material and the second perovskite semiconductor material; and
dielectric materials between the source/drain metals and the perovskite gate materials.

2. The device of claim 1, wherein the first perovskite gate material, the first perovskite ferroelectric material, the first perovskite semiconductor material, the second perovskite ferroelectric material, the second perovskite gate material, the third perovskite ferroelectric material, the second perovskite semiconductor material, the fourth perovskite ferroelectric material, and the third perovskite gate material form a continuous perovskite structure.

3. The device of claim 1, wherein a width of the first perovskite semiconductor material and a width of the second perovskite semiconductor material are greater than a width of each of the first perovskite ferroelectric material, the second perovskite ferroelectric material, the third perovskite ferroelectric material, and the fourth perovskite ferroelectric material.

4. The device of claim 1, wherein first perovskite gate material, the second perovskite gate material, and the third perovskite gate material comprise Strontium, Ruthenium, and Oxygen.

5. The device of claim 1, wherein the first perovskite ferroelectric material, the second perovskite ferroelectric material, the third perovskite ferroelectric material, and the fourth perovskite ferroelectric material comprise Barium, Titanium, and Oxygen.

6. The device of claim 1, wherein the first perovskite semiconductor material and the second perovskite semiconductor material comprise Lanthanum, Barium, Tin, and Oxygen.

7. The device of claim 6, wherein the Lanthanum is between 1% and 5% of the total of Lanthanum and Barium in the first perovskite semiconductor material and the second perovskite semiconductor material.

8. The device of claim 1, wherein the dielectric materials between the source/drain metals and the perovskite gate materials comprise Silicon and Nitrogen.

9. The device of claim 1, wherein the dielectric materials between the source/drain metals and the perovskite gate materials comprise Boron and Nitrogen.

10. The device of claim 1, further comprising a substrate, the first perovskite gate material on the substrate.

11. The device of claim 10, wherein the substrate comprises Strontium, Titanium, and Oxygen.

12. An integrated circuit device comprising:
a plurality of stacked transistors; and
one or more interconnect layers, the interconnect layers electrically connecting the transistors;
wherein the stacked transistors each include:
a first perovskite gate material;
a first perovskite ferroelectric material on the first perovskite gate material;
a first perovskite semiconductor material on the first perovskite ferroelectric material;
a second perovskite ferroelectric material on the first perovskite semiconductor material;
a second perovskite gate material on the second perovskite ferroelectric material;
a third perovskite ferroelectric material on the second perovskite gate material;
a second perovskite semiconductor material on the third perovskite ferroelectric material;
a fourth perovskite ferroelectric material on the second perovskite semiconductor material;
a third perovskite gate material on the fourth perovskite ferroelectric material;
a first source/drain metal adjacent a first side of each of the first perovskite semiconductor material and the second perovskite semiconductor material;
a second source/drain metal adjacent a second side opposite the first side of each of the first perovskite semiconductor material and the second perovskite semiconductor material; and
dielectric materials between the source/drain metals and the perovskite gate materials.

13. The integrated circuit device of claim 12, wherein the first perovskite gate material, the first perovskite ferroelectric material, the first perovskite semiconductor material, the second perovskite ferroelectric material, the second perovskite gate material, the third perovskite ferroelectric material, the second perovskite semiconductor material, the fourth perovskite ferroelectric material, and the third perovskite gate material form a continuous perovskite structure in each transistor.

14. The integrated circuit device of claim 12, wherein a width of the first perovskite semiconductor material and a width of the second perovskite semiconductor material are greater than a width of each of the first perovskite ferroelectric material, the second perovskite ferroelectric material, the third perovskite ferroelectric material, and the fourth perovskite ferroelectric material.

15. The integrated circuit device of claim 12, wherein first perovskite gate material, the second perovskite gate material, and the third perovskite gate material comprise Strontium, Ruthenium, and Oxygen.

16. The integrated circuit device of claim 12, wherein the first perovskite ferroelectric material, the second perovskite ferroelectric material, the third perovskite ferroelectric material, and the fourth perovskite ferroelectric material comprise Barium, Titanium, and Oxygen.

17. The integrated circuit device of claim 12, wherein the first perovskite semiconductor material and the second perovskite semiconductor material comprise Lanthanum, Barium, Tin, and Oxygen.

18. The integrated circuit device of claim 17, wherein the Lanthanum is between 1% and 5% of the total of Lanthanum and Barium in the first perovskite semiconductor material and the second perovskite semiconductor material.

19. The integrated circuit device of claim 12, wherein the dielectric materials between the source/drain metals and the perovskite gate materials comprise Silicon and Nitrogen.

20. The integrated circuit device of claim 12, wherein the dielectric materials between the source/drain metals and the perovskite gate materials comprise Boron and Nitrogen.

21. The integrated circuit device of integrated circuit device, wherein the substrate comprises Strontium, Titanium, and Oxygen.

22. A method of forming a stacked transistor device, comprising:
forming a first perovskite gate material on a substrate;
forming a first perovskite ferroelectric material on the first perovskite gate material;
forming a first perovskite semiconductor material on the first perovskite ferroelectric material;
forming a second perovskite ferroelectric material on the first perovskite semiconductor material;
forming a second perovskite gate material on the second perovskite ferroelectric material;
forming a third perovskite ferroelectric material on the second perovskite gate material;
forming a second perovskite semiconductor material on the third perovskite ferroelectric material;
forming a fourth perovskite ferroelectric material on the second perovskite semiconductor material;
forming a third perovskite gate material on the fourth perovskite ferroelectric material;
forming a first source/drain metal adjacent a first side of each of the first perovskite semiconductor material and the second perovskite semiconductor material; and
forming a second source/drain metal adjacent a second side opposite the first side of each of the first perovskite semiconductor material and the second perovskite semiconductor material.

23. The method of claim 22, wherein the first perovskite gate material, the first perovskite ferroelectric material, the first perovskite semiconductor material, the second perovskite ferroelectric material, the second perovskite gate material, the third perovskite ferroelectric material, the second perovskite semiconductor material, the fourth perovskite ferroelectric material, and the third perovskite gate material are formed without breaking a vacuum.

24. The method of claim 22, further comprising, before forming the first source/drain metal and the second source/drain metal:
laterally etching each side of the first perovskite gate material, the second perovskite gate material, and the third perovskite gate material;
forming dielectric materials adjacent on each side of the first perovskite gate material, the second perovskite gate material, and the third perovskite gate material; and
laterally etching each side of the dielectric materials.

25. The method of claim 22, further comprising, before forming the first source/drain metal and the second source/drain metal, laterally etching each side of the first perovskite ferroelectric material, the second perovskite ferroelectric material, the third perovskite ferroelectric material, and the fourth perovskite ferroelectric material.
